(19) United States
(12) Patent Application Publication
(10) Pub. No.: US 2010/0284148 A1
(43) Pub. Date: Nov. 11, 2010

(54) ELECTRONIC DEVICE ENCLOSURE

(75) Inventors: ZHENG-HENG SUN, Tu-Cheng (TW); XIAO-FENG MA, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/606,107

(22) Filed: Oct. 26, 2009

(30) Foreign Application Priority Data
May 6, 2009 (CN) 200910302124.4

(51) Int. Cl. H05K 7/20

(52) U.S. Cl. 361/692

(57) ABSTRACT

An electronic device enclosure includes a wall defining a slot therein, and a number of spaced bent plates formed on the wall bestriding the slot. Every two adjacent bent plates bound an opening in communication with the slot. The slot can allow more airflow to pass therethrough, and the number of bent plates can guide more airflow slantingly flowing towards the wall of the electronic device enclosure into or out the electronic device enclosure through the openings.

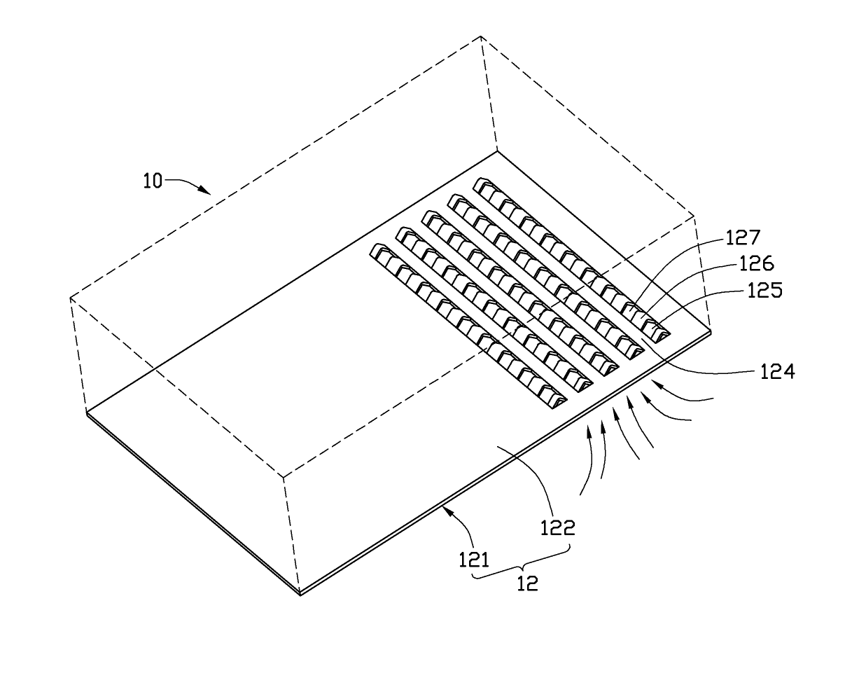

### BACKGROUND

1. Technical Field

The present disclosure relates to an electronic device enclosure.

2. Description of Related Art

An electronic device, such as a computer or a server, generally defines a plurality of ventilation holes in an enclosure of the electronic device. However, because the holes are the only way for air to get inside of this type of enclosure, air circulating efficiency is low.

### BRIEF DESCRIPTION OF THE DRAWING

The drawing is an isometric view of an embodiment of an electronic device enclosure.

### DETAILED DESCRIPTION

Referring to the drawing, an embodiment of an electronic device enclosure 10 includes a planar wall 12. The wall 12 includes a first surface 121 facing an outside environment of the electronic device enclosure 10, and a second surface 122 facing inside the electronic device enclosure 10. A plurality of spaced elongated slots 125 is defined in a predetermined ventilation area 124 of the wall 12. A plurality of spaced bent plates 126 is formed on the wall 12, bestriding each slot 125, with opposite ends of each bent plate 126 integrally connected to opposite elongated sides bounding each slot 125. In another embodiment, the plurality of bent plates 126 may be detachably attached to the opposite elongated sides bounding each slot 125. The bent plates 126 are bent towards the inside of the electronic device enclosure 10 and located inside the electronic device enclosure 10. Every two adjacent bent plates 126 bound an opening 127 in communication with the slot 125, together with the opposite elongated sides bounding the slot 125. In this embodiment, each bent plate 126 is bent to form an obtuse angle. In other embodiments, the plurality of bent plates 126 may be bent to form right angles or acute angles, or the bent plates 126 may be arc shaped.

In use, airflow is forced to flow towards the electronic device enclosure 10 from different directions as indicated by arrows shown in the drawing. Because the openings 127 communicate with the slots 125, and the bent plates 126 are bent towards the inside of the electronic device enclosure 10, the plurality of elongated slots 125 can allow a great deal of air to pass therethrough, and the bent plates 126 can guide airflow to slantingly flow relative to the wall 12 of the electronic device enclosure 10 into the inside of the electronic device enclosure 10 through the openings 127, which provides better air circulating efficiency.

In another embodiment, the plurality of bent plates 126 may be bent towards the outside of the electronic device enclosure 10 and located outside the electronic device enclosure 10 when the airflow is forced out from the inside of the electronic device enclosure 10 by an exhaust fan.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An electronic device enclosure, comprising:
a wall comprising a first surface and a second surface opposite to the first surface, the wall defining a ventilation area, wherein the ventilation area defines at least one elongated slot; and
a plurality of spaced bent plates formed on the wall bestriding opposite elongated sides bounding each slot, with opposite ends of each of the plurality of bent plates connected to the opposite sides bounding the corresponding slot, wherein every two adjacent bent plates bound an opening in communication with the corresponding slot through which airflow passes.

2. The electronic device enclosure of claim 1, wherein the first surface facing an outside of the electronic device enclosure, and the second surface facing an inside of the electronic device enclosure, the plurality of bent plates are bent towards the inside of the electronic device enclosure and located inside the electronic device enclosure.

3. The electronic device enclosure of claim 1, wherein the first surface facing an outside of the electronic device enclosure, and the second surface facing an inside of the electronic device enclosure, the plurality of bent plates are bent towards the outside of the electronic device enclosure and generally located outside the electronic device enclosure.
